(19) United States
(12) Patent Application Publication
(10) Pub. No.: US 2023/0215832 A1
(43) Pub. Date: Jul. 6, 2023

(54) NON CONDUCTIVE FILM, METHOD FOR FORMING NON CONDUCTIVE FILM, CHIP PACKAGE STRUCTURE, AND METHOD FOR PACKAGING CHIP

(71) Applicant: CHANGXIN MEMORY TECHNOLOGIES, INC., Hefei City (CN)

(72) Inventor: CHIH-WEI CHANG, Hefei City (CN)

(73) Assignee: CHANGXIN MEMORY TECHNOLOGIES, INC., Hefei City (CN)

(21) Appl. No.: 17/662,641

(22) Filed: May 9, 2022

Related U.S. Application Data
(63) Continuation of application No. PCT/CN2022/076142, filed on Feb. 14, 2022.

(30) Foreign Application Priority Data
Jan. 5, 2022 (CN) 202210003808.X

(51) Int. Cl. H01L 23/00; H01L 25/065

(52) U.S. Cl. CPC H01L 24/29; H01L 24/27; H01L 24/32; H01L 24/83; H01L 25/0657; H01L 2224/3201; H01L 2224/8309; H01L 2224/27614; H01L 2224/29005; H01L 2224/29011; H01L 2224/29016; H01L 2224/29076; H01L 2224/29187; H01L 2224/32058; H01L 2224/32059; H01L 2224/32145; H01L 2224/32221; H01L 2224/83203; H01L 2225/06524; H01L 2225/06527

(57) ABSTRACT

A Non Conductive Film (NCF) at least includes a first film layer and a second film layer. A surface of the first film layer is provided with a grid-shaped groove structure, and a depth of each groove of the groove structure is less than a thickness of the first film layer. The second film layer is located in the groove in the surface of the first film layer. The fluidity of the first film layer is greater than the fluidity of the second film layer under the same condition.

### CROSS-REFERENCE TO RELATED APPLICATIONS

This is a continuation of International Patent Application No. PCT/CN2022/076142 filed on Feb. 14, 2022, which claims priority to Chinese Patent Application No. 202210003808.X filed on Jan. 05, 2022. The disclosures of these applications are hereby incorporated by reference in their entirety.

### BACKGROUND

In a three-dimensional wafer packaging process technology, a Non Conductive Film (NCF) is configured to bond an upper chip and a lower chip together during stacking and packaging. The NCF is bonded to the whole wafer, and has an effect of protecting a bump. The wafer is processed through a Backside Via Reveal (BVR) process and a dicing process to form a plurality of chips, so as to stack a chip structure. When the chips are stacked onto one another, the chips are bonded together through a Thermal Compression Bond (TCB) process. However, the NCF between the chips will be extruded outside the chips due to heating and extruding caused by the TCB process. A relatively thick NCF barrier layer is formed at the edge of the chip, and the relatively thick barrier layer extruded outside the chip will affect the stacking of a next chip.

### SUMMARY

The disclosure relates to the technical field of semiconductors, and relates, but is not limited, to a Non Conductive Film (NCF), a method for forming the NCF, a chip package structure, and a method for packaging a chip.

In view of this, the embodiments of the disclosure provide a Non Conductive Film (NCF), a method for forming the NCF, a chip package structure, and a method for packaging a chip.

In a first aspect, the embodiments of the disclosure provide an NCF at least including a first film layer and a second film layer.

A surface of the first film layer is provided with a grid-shaped groove structure, and a depth of each groove of the groove structure is less than a thickness of the first film layer.

The second film layer is located in the groove in the surface of the first film layer.

Fluidity of the first film layer is greater than fluidity of the second film layer under a same condition.

In a second aspect, the embodiments of the disclosure provide a method for forming a Non Conductive Film (NCF), including the following operations.

A supporting layer is provided.

A second film layer provided with a plurality of grooves is formed on the supporting layer. The plurality of grooves expose a surface of the supporting layer.

A first film layer is formed in the plurality of grooves and on a surface of the second film layer, in which fluidity of the first film layer is greater than fluidity of the second film layer under a same condition.

In a third aspect, the embodiments of the disclosure provide a chip package structure including a chip stack structure and a substrate.

The chip stack structure includes a plurality of chips stacked onto one another, and any two adjacent chips of the plurality of chips are bonded together through the NCF described above.

The chip stack structure is bonded to the substrate, and the NCF is filled between the substrate and the chip stack structure.

In a fourth aspect, the embodiments of the disclosure provide a chip stacking method including the following operations.

The chip stack structure is formed. The chip stack structure includes a plurality of chips stacked onto one another, and any two adjacent chips of the plurality of chips are bonded together through the NCF described above.

The chip stack structure is bonded to a substrate, to realize packaging of the plurality of chips.

### BRIEF DESCRIPTION OF THE DRAWINGS

In the drawings (which are not necessarily drawn to scale), similar reference numerals may describe similar parts in different views. Similar reference numerals with different letter suffixes may represent different examples of similar parts. The drawings generally illustrate the various embodiments discussed herein by way of examples rather than limitation.

FIG. 1A illustrates a first schematic diagram showing the overflow of a Non Conductive Film (NCF) during packaging in the embodiments of the disclosure.

FIG. 1B illustrates a second schematic diagram showing the overflow of a Non Conductive Film (NCF) during packaging in the embodiments of the disclosure.

FIG. 2A illustrates a first schematic diagram of the NCF according to the embodiments of the disclosure.

FIG. 2B illustrates a second schematic diagram of the NCF according to the embodiments of the disclosure.

FIG. 2C illustrates a third schematic diagram of the NCF according to the embodiments of the disclosure.

FIG. 2D illustrates a fourth schematic diagram of the NCF according to the embodiments of the disclosure.

FIG. 2E illustrates a fifth schematic diagram of the NCF according to the embodiments of the disclosure.

FIG. 3 illustrates a flowchart of a method for forming the NCF according to the embodiments of the disclosure.

FIG. 4A illustrates a first schematic diagram showing a process for forming the NCF according to the embodiments of the disclosure.

FIG. 4B illustrates a second schematic diagram showing a process for forming the NCF according to the embodiments of the disclosure.

FIG. 4C illustrates a third schematic diagram showing a process for forming the NCF according to the embodiments of the disclosure.

FIG. 4D illustrates a fourth schematic diagram showing a process for forming the NCF according to the embodiments of the disclosure.

FIG. 4E illustrates a fifth schematic diagram showing a process for forming the NCF according to the embodiments of the disclosure.

FIG. 5 illustrates a schematic diagram of a chip package structure according to the embodiments of the disclosure.

FIG. 6 illustrates a flowchart of a method for packaging a chip according to the embodiments of the disclosure.

### DETAILED DESCRIPTION

Exemplary embodiments of the disclosure will be described below in detail with reference to the drawings. Although the exemplary embodiments s of the disclosure are shown in the drawings, it should be understood that the disclosure may be implemented in various forms and should not be limited by the specific embodiments described herein. On the contrary, these embodiments are provided to enable a more thorough understanding of the disclosure and to fully convey the scope of the disclosure to those skilled in the art.

In the following description, a large number of specific details are given in order to provide a more thorough understanding of the disclosure. However, it will be apparent to those skilled in the art that the disclosure may be implemented without one or more of these details. In other examples, in order to avoid confusion with the disclosure, some technical features known in the art are not described. That is, all the features of the actual embodiments are not described here, and the known functions and structures are not described in detail.

In the drawings, the dimensions of layers, areas, and elements and their relative dimensions may be exaggerated for clarity. Throughout the description, the same reference numeral represents the same element.

It is to be understood that the expression that an element or layer is “above”, “adjacent to”, “connected to”, or “coupled to” another element or layer may refer to that the element or layer is directly above, adjacent to, connected to or coupled to another element or layer, or there may be an intermediate element or layer. On the contrary, the expression that an element is “directly on”, “directly adjacent to”, “directly connected to” or “directly coupled to” another element or layer refers to that there is no intermediate element or layer. It is to be understood that although various elements, components, areas, layers, and/or parts may be described with terms first, second, third, etc., these elements, components, areas, layers, and/or parts should not be limited to these terms. These terms are used only to distinguish one element, component, area, layer or part from another element, component, area, layer or part. Therefore, a first element, component, area, layer, or part discussed below may be represented as a second element, component, area, layer, or part without departing from the teaching of the disclosure. However, when second element, component, area, layer, or part is discussed, it does not mean that the first element, component, area, layer, or part must exist in the disclosure.

The terms used herein are intended only to describe specific embodiments and are not a limitation of the disclosure. As used herein, singular forms “a/an”, “one”, and “the” may also be intended to include the plural forms, unless otherwise specified types in the context. It is also to be understood that when terms “composed of” and/or “including” are used in this specification, the presence of the features, integers, operations, operations, elements, and/or components may be determined, but the presence or addition of one or more other features, integers, operations, operations, elements, components, and/or groups is also possible. As used herein, terms “and/or” includes any and all combinations of the related listed items.

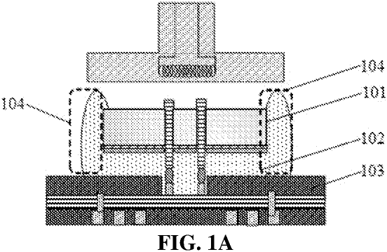

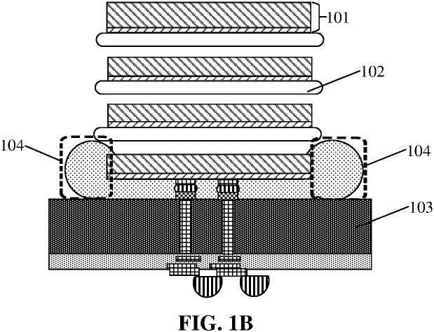

In the embodiments of the disclosure, in a chip packaging process, a Non Conductive Film (NCF) is configured to bond adjacent chips together or to be filled between the chip and a substrate for packaging. Usually, in the chip packaging process, the chips are bonded together or the chip and the substrate are bonded together by heating and compressing by a TCB process. However, during heating, the NCF will be extruded outside the chips, and excessive thickness of the extruded NCF will affect the stacking of the next chip. As shown in FIG. 1A and FIG. 1B, NCF 102 between a chip 101 and a substrate 103 will be extruded outside the chip to form a relatively thick NCF barrier layer 104, and the relatively thick NCF barrier layer 104 will affect the stacking of the next chip.

On the basis of the abovementioned problems in the abovementioned solution in the embodiments of the disclosure, the embodiments of the disclosure provide an NCF, a method for forming an NCF, a chip package structure, and a method for packaging a chip. The NCF includes a first film layer and a second film layer. A surface of the first film layer is provided with a grid-shaped groove structure. The second film layer is located in the groove in the surface of the first film layer, and the fluidity of the first film layer is greater than the fluidity of the second film layer under the same condition. The NCF provided by the embodiments of the disclosure is composed of the first film layer and the second film layer with different fluidity, and the second film layer with low fluidity is grid-shaped, so that the second film layer with low fluidity has a certain supporting effect when the chips are bonded together by using the NCF provided by the embodiments of the disclosure. Therefore, too much NCF cannot be extruded outside the chips, and then a subsequent stacking process of the chips cannot be affected.

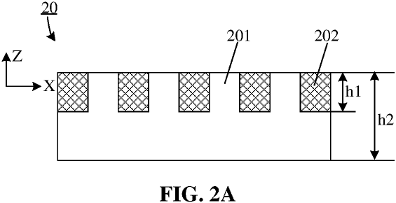

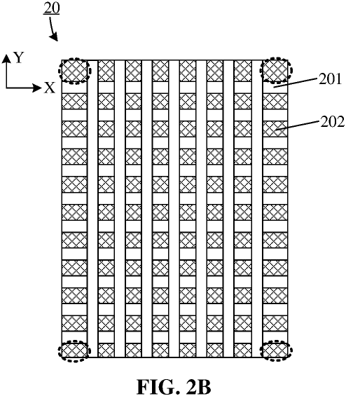

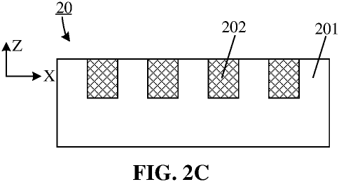

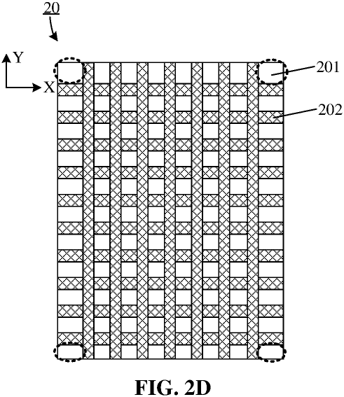

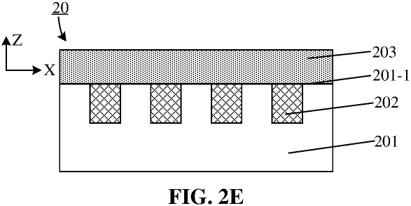

FIG. 2A to FIG. 2E illustrate schematic diagrams of the NCF according to the embodiments of the disclosure. FIG. 2B and FIG. 2D are top views. As shown in FIG. 2A and FIG. 2B, the NCF 20 includes a first film layer 201 and a second film layer 202.

The surface of the first film layer 201 is provided with a grid-shaped groove structure, and the depth of each groove of the groove structure is less than the thickness of the first film layer 201. That is to say, the dimension h1 of each groove in a Z-axis direction is less than the dimension h2 of the first film layer 201 in the Z-axis direction.

The second film layer 202 is located in the groove in the surface of the first film layer 201. A top surface of the second film layer is flush with a top surface of the first film layer.

In the embodiments of the disclosure, the fluidity of the first film layer 201 is greater than the fluidity of the second film layer 202 under the same condition.

In some embodiments, the first film layer 201 includes a non-conductive material with a first preset concentration, and the second film layer 202 includes a non-conductive material with a second preset concentration, in which the second preset concentration is greater than the first preset concentration. In the embodiments of the disclosure, the non-conductive material may be SiO₂, Al₂O₃, or a composite material of the SiO₂ and the Al₂O₃.

In some embodiments, the first film layer 201 has a first melting point, the second film layer 202 has a second melting point, and the second melting point is greater than the first melting point. That is, in the embodiments of the disclosure, the melting point of the second film layer with low fluidity is greater than the melting point of the first film layer with high fluidity.

In the embodiments of the disclosure, the concentration of a conductive material of the first film layer is less than the concentration of the conductive material of the second film layer, and the melting point of the first film layer is less than the melting point of the second film layer. Therefore, the second film layer has lower fluidity and is less likely to be melted than the first film layer. In this way, the second film layer has a certain effect of supporting the first film layer in a subsequent process of melting the first film layer and the second film layer to stack the chips onto one another by the TCB process, which can prevent the conductive material from overflowing excessively.

In some embodiments, with reference to FIG. 2A and FIG. 2B, the second film layer 202 is at least located at a corner of the NCF 20 (the position denoted by a dotted box in FIG. 2B).

In other embodiments, as shown in FIG. 2C and FIG. 2D, the second film layer 202 may also be located at a position (the position denoted by a dotted box in FIG. 2D) of the NCF 20 adjacent to the corner. That is to say, the first film layer may be located at the corner of the NCF 20 (corresponding to FIG. 2C and FIG. 2D), or the second film layer may be located at the corner of the NCF 20 (corresponding to FIG. 2A and FIG. 2B).

In some embodiments, as shown in FIG. 2E, the NCF 20 further includes a supporting layer 203. A first surface 201-1 of the first film layer 201 is provided with a grid-shaped groove structure. The first surface 201-1 is any surface of the first film layer 201 in the thickness direction (that is, the Z-axis direction) of the first film layer. The supporting layer 203 is located on a surface of the second film layer 202 and a part of the first surface 201-1 of the first film layer 201.

In some embodiments, the material of the supporting layer 203 may be any material which is suitable and easily removable. The supporting layer 203 has a preset viscosity value, and the supporting layer does not have fluidity at the preset viscosity value. The supporting layer 203 performs an effect of supporting the first film layer and the second film layer.

The NCF provided by the embodiments of the disclosure is composed of the first film layer and the second film layer with different fluidity, and the second film layer with low fluidity is grid-shaped, so that the second film layer with low fluidity has a certain supporting effect when the chips are bonded together by using the NCF provided by the embodiments of the disclosure, too much NCF cannot be extruded outside the chips, and then a subsequent stacking process of the chips cannot be affected.

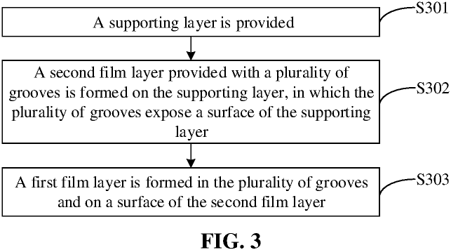

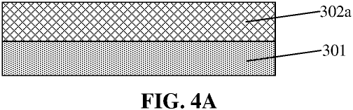

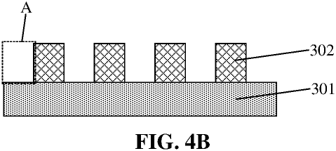

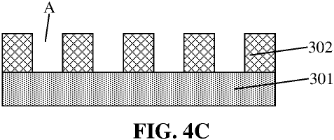

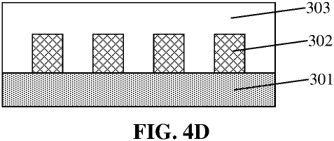

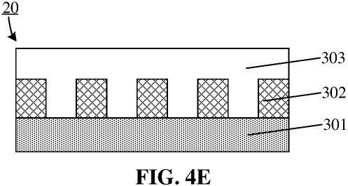

The embodiments of the disclosure provide a method for forming an NCF. FIG. 3 illustrates a flowchart of a method for forming the NCF according to embodiments of the disclosure. FIG. 4A to FIG. 4E illustrate schematic diagrams showing a process of forming the NCF according to the embodiments of the disclosure. As shown in FIG. 3, the method for forming the NCF includes the following operations.

At S301, a supporting layer is provided.

In the embodiment of the present disclosure, the supporting layer has a preset viscosity value, and the supporting layer does not have fluidity at the preset viscosity value. The supporting layer is configured to support a subsequently formed structure.

At S302, a second film layer provided with a plurality of grooves is formed on the supporting layer. The plurality of grooves expose a surface of the supporting layer.

In some embodiments, S302 may include the following operations.

At S3021, an initial second film layer is formed on the supporting layer.

As shown in FIG. 4A, the initial second film layer 302a is formed on the surface of the supporting layer 301. In the embodiments of the disclosure, the initial second film layer may be formed through any suitable deposition process, such as a Chemical Vapor Deposition (CVD) process, a Physical Vapor Deposition (PVD) process, an Atomic Layer Deposition (ALD) process, a spin coating process, or a coating process.

At S3022, the initial second film layer is etched through a dry etching process, to form the second film layer provided with the plurality of grooves.

In the embodiments of the disclosure, the dry etching process includes a plasma etching process, a reactive ion etching process or an ion milling process.

As shown in FIG. 4B and FIG. 4C, the initial second film layer 302a is etched through a dry etching process, to form the second film layer 302 provided with the plurality of grooves A, in which the grooves A expose the surface of the supporting layer 301.

In the embodiments of the disclosure, the grooves A are at least located at the corner of the second film layer (as shown in FIG. 4B); or the grooves A are at least located at a position of the second film layer adjacent to the corner (as shown in FIG. 4C).

At S303, a first film layer is formed in the plurality of grooves and on a surface of the second film layer.

As shown in FIGS. 4D and 4E, a first film layer 303 is formed in the grooves A and on the surface of the second film layer 302, in which a bottom surface of the first film layer 303 is of a grid-shaped groove structure.

In the embodiments of the disclosure, the first film layer may be formed by any suitable deposition process, such as a coating process.

In the embodiments of the disclosure, the fluidity of the first film layer 303 is greater than the fluidity of the second film layer 302 under the same condition. The material of the first film layer is the same as the material of the second film layer, but the content of the material of the first film layer is different from the content of the material of the second film layer.

In some embodiments, the first film layer has a first melting point, the second film layer has a second melting point, and the second melting point is greater than the first melting point.

In the embodiments of the disclosure, the fluidity of the first film layer is greater than the fluidity of the second film layer, and the second film layer is less likely to be molten than the first film layer. Therefore, the second film layer may perform a certain effect of supporting the first film layer in a subsequent process of melting the first film layer and the second film layer to stack the chips onto one another by the TCB process, which can prevent the conductive material of the first film layer from overflowing excessively to affect a subsequent chip stacking process.

The NCF formed in the embodiments of the disclosure is similar to the NCF in the abovementioned embodiments. The technical features not disclosed in detail in the embodiments of the disclosure refer to the abovementioned embodiments for understanding, which will not be elaborated here.

The NCF formed by the method for forming the NCF according to the embodiments of the disclosure is composed of a first film layer and a second film layer with different fluidity, and the second film layer with low fluidity is grid-shaped, such that the second film layer with low fluidity has a certain supporting effect when chips are bonded together by using the NCF formed by the embodiments of the disclosure, which can prevent the NCF from overflowing excessively, and then a subsequent stacking process of the chips will not be affected.

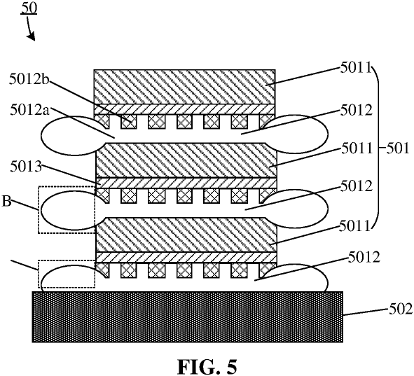

The embodiments of the disclosure provide a chip package structure. FIG. 5 illustrates a schematic diagram of a chip package structure according to the embodiments of the disclosure. As shown in FIG. 5, the chip package structure 50 includes a chip stack structure 501 and a substrate 502.

The chip stack structure 501 includes a plurality of chips 5011 stacked onto one another, and any two adjacent chips of the plurality of chips are bonded together through an NCF 5012. The substrate 502 and the chip stack structure 501 are bonded together, and an NCF 5012 is filled between the substrate 502 and the chip stack structure 501.

In some embodiments, a metal interconnection layer 5013 is formed on a face of each chip 5011. The metal interconnection layer is configured to deliver an electrical signal inside the chip 5011. In addition, the interconnection between the chips 5011 is realized by a through silicon via (not shown in the drawings) arranged in each chip 5011 and a solder ball (not shown) electrically connected with the through silicon via.

In the embodiments of the disclosure, the NCF 5012 includes a first film layer 5012a and a second film layer 5012b. The fluidity of the first film layer 5012a is greater than the fluidity of the second film layer 5012b. The surface of the first film layer 5012a is provided with a grid-shaped groove structure, and the second film layer 5012b is located in the groove in the surface of the first film layer 5012a. Therefore, the second film layer 5012b in the embodiments of the disclosure is also provided with a grid-shaped structure.

Since the NCF in the embodiments of the disclosure is composed of two film layers with different fluidity, in a chip packaging process, the grid-shaped second film layer with low fluidity will provide a high supporting effect to prevent the first film layer with high-fluidity in the NCF from being extruded and overflowing outwards, and then a subsequent chip stacking process will not be affected.

As shown by a dotted box B shown in FIG. 5, only a part of the first film layer 5012a with low fluidity is extruded outside the chip due the supporting effect of the second film layer 5012b, and the extruded part of the first film layer 5012a will not affect a subsequent stacking process.

The NCF of the chip stack structure provided by the embodiments of the disclosure is similar to the NCF in the abovementioned embodiments. The technical features not disclosed in detail in the embodiments of the disclosure refer to the abovementioned embodiments for understanding, which will not be elaborated here.

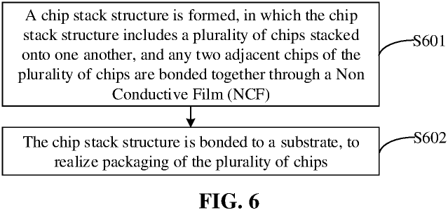

In addition, the embodiments of the disclosure further provide a method for packaging a chip. FIG. 6 illustrates a flowchart of a method for packaging a chip according to the embodiments of the disclosure. As shown in FIG. 6, the method for packaging the chip includes the following operations.

At S601, a chip stack structure is formed, in which the chip stack structure includes a plurality of chips stacked onto one another, and any two adjacent chips of the plurality of chips are bonded together through an NCF.

In some embodiments, the chip stack structure may be formed by the following operations.

At S6011, a plurality of chips are provided, in which the NCF is arranged on a first face of each chip, and a metal interconnection layer is arranged on a second face of each chip. The first face and the second face are two faces of each chip, which are opposite to each other in thickness direction of each chip.

In some embodiments, the operation that a plurality of chips are provided includes the following operations.

At S1, a wafer is provided, in which a circuit structure with a specific function is formed in the wafer.

At S2, the NCF is formed on a surface of the wafer.

In the embodiments of the disclosure, the operation that the NCF is formed on the surface of the wafer may include an operation that the NCF is bonded to the surface of the wafer, or an operation that the NCF is formed on the surface of the wafer through a deposition process and an etching process.

In the embodiments of the disclosure, the NCF at least includes a first film layer and a second film layer. The surface of the first film layer is provided with a grid-shaped groove structure, and the depth of each groove of the groove structure is less than the thickness of the first film layer. The second film layer is located in the groove in the surface of the first film layer. The fluidity of the first film layer is greater than the fluidity of the second film layer under the same condition.

In embodiments of the disclosure, a first surface of the first film layer is provided with a grid-shaped groove structure, and a supporting layer is arranged on the surface of the second film layer and a part of the first surface of the first film layer. The second surface of the first film layer is in contact with the first face of the chip. The first surface and the second surface are two surfaces of the first film layer, which are opposite to each other in the thickness direction of the first film layer.

At S3, the wafer is cut to form the plurality of chips.

At S6012, the first face of a first chip of the plurality of chips is aligned with the second face of a second chip of the plurality of chips.

At S6013, the first chip is at least stacked on the second chip by the NCF to form the chip stack structure.

In the embodiments of the disclosure, the plurality of chips are stacked onto one another in a face to back manner.

In some embodiments, before the first chip is bonded to the second chip, the method further includes the following operation. The supporting layer is removed.

In the embodiments of the disclosure, the supporting layer may be torn off only, or the supporting layer may be removed by a wet etching process or other processes.

In some embodiments, S6013 may include the following operations.

The first chip is at least bonded to the second chip by the NCF through a vacuum bonding process and a TCB process, to obtain the chip stack structure.

In the embodiments of the disclosure, a grid-shaped NCF (that is, a second film layer) with low fluidity is bonded through the vacuum bonding process. The vacuum bonding process does not need to consider the influence of low fluidity on bubble removal. An NCF (that is, a first film layer) with high fluidity is bonded through the TCB process without a vacuum environment, and the NCF with high fluidity can improve the bubble removal efficiency. Further, the grid-shaped NCF with low fluidity can prevent the NCF with high fluidity from being extruded outwards or upwards during bonding.

At S602, the chip stack structure is bonded to a substrate, to realize the packaging of the plurality of chips.

A conductive pillar and a plurality of conductive structures are formed in the substrate. In the embodiments of the disclosure, after the chip stack structure is formed, the chip stack structure is bonded to the substrate, to realize the electrical signal communication between the chip stack structure and the substrate.

In the embodiments of the disclosure, the NCF is also filled between the substrate and the chip stack structure, and the sealing between the chip stack structure and the substrate is realized through the NCF.

The NCF used in the embodiments of the disclosure is similar to the NCF in the abovementioned embodiments. The technical features not disclosed in detail in the embodiments of the disclosure refer to the above-mentioned embodiment for understanding, which will not be elaborated here.

It is to be noted that since the NCF in the embodiments of the disclosure is composed of two film layers with different fluidity, in a chip packaging process, a grid-shaped second film layer with low fluidity will provide a high supporting effect to prevent a first film layer with high fluidity in the NCF from being extruded and overflowing outwards.

The method for packaging the chip in the embodiments of the disclosure is similar to the chip package structure in the abovementioned embodiments. The technical features not disclosed in detail in the embodiments of the disclosure refer to the abovementioned embodiments for understanding, which will not be elaborated here.

In the method for packaging the chip provided by the embodiments of the disclosure, the NCF is composed of a first film layer and a second film layer with different fluidity, and the second film layer with low fluidity is grid-shaped, so that the second film layer with low fluidity has a certain supporting effect when the chips are bonded together, too much NCF will not be extruded outside the chips, and then a subsequent stacking process of the chips cannot be affected.

In several embodiments provided by the disclosure, it is to be understood that the disclosed device and method may be implemented in a non-target mode. The device embodiment described above is only schematic, and for example, division of the units is only logic function division, and other division manners may be adopted during practical implementation. For example, a plurality of units or components may be combined with each other or integrated into another system, or some characteristics may be neglected or not executed. In addition, the components shown or discussed are coupled to each other, or directly coupled to each other.

The abovementioned units described as separate parts may be or may not be physically separated, and the parts shown as units may be or may not be physical elements, which may be located in one place or distributed to a plurality of network elements. Part or all of the units may be selected to achieve the objectives of the solutions of the embodiments according to practical requirements.

The characteristics disclosed in several method or device embodiments provided in the disclosure may be freely combined with each other without conflicts to obtain new method embodiments or device embodiments.

The abovementioned descriptions are only some implementation modes of the embodiments of the disclosure, but the scope of protection of the embodiments of the disclosure are limited thereto. Any variation or replacement readily figured out by a person skilled in the art within the technical scope disclosed in the disclosure shall fall within the scope of protection of the disclosure. Therefore, the scope of protection of the embodiments of the disclosure shall be subject to the scope of protection of the claims.

What is claimed is:

1. A Non Conductive Film (NCF), at least comprising: a first film layer and a second film layer,
wherein a surface of the first film layer is provided with a grid-shaped groove structure, and a depth of each groove of the groove structure is less than a thickness of the first film layer,
the second film layer is located in the groove in the surface of the first film layer, and
fluidity of the first film layer is greater than fluidity of the second film layer under a same condition.

2. The NCF of claim 1, wherein the first film layer comprises a non-conductive material with a first preset concentration, and the second film layer comprises a non-conductive material with a second preset concentration, and
wherein the second preset concentration is greater than the first preset concentration.

3. The NCF of claim 2, wherein the first film layer has a first melting point, and the second film layer has a second melting point, and
wherein the second melting point is greater than the first melting point.

4. The NCF of claim 3, wherein the second film layer is at least located at a corner of the NCF, or the second film layer is at least located at a position adjacent to the corner.

5. The NCF of claim 1, further comprising a supporting layer,
wherein a first surface of the first film layer is provided with a grid-shaped groove structure, wherein the first surface is any surface of the first film layer in a thickness direction of the first film layer, and
the supporting layer is located on a surface of the second film layer and a part of the first surface of the first film layer.

6. A method for forming a Non Conductive Film (NCF), comprising:
providing a supporting layer;
forming a second film layer provided with a plurality of grooves on the supporting layer, wherein the plurality of grooves expose a surface of the supporting layer; and
forming a first film layer in the plurality of grooves and on a surface of the second film layer, wherein fluidity of the first film layer is greater than fluidity of the second film layer under a same condition.

7. The method of claim 6, wherein forming the second film layer provided with the plurality of grooves on the supporting layer comprises:
forming an initial second film layer on the supporting layer; and
etching the initial second film layer through a dry etching process, to form the second film layer provided with the plurality of grooves.

8. The method of claim 6, wherein the grooves are at least located at a corner of the second film layer, or the grooves are at least located at a position adjacent to the corner.

9. The method of claim 8, wherein the supporting layer has a preset viscosity value, and the supporting layer does not have fluidity at the preset viscosity value.

10. A chip package structure, comprising:
a chip stack structure, wherein the chip stack structure comprises a plurality of chips stacked onto one another, and any two adjacent chips of the plurality of chips are bonded together through the NCF according to claim 1; and
a substrate, wherein the chip stack structure is bonded to the substrate, and the NCF is filled between the substrate and the chip stack structure.

11. A method for packaging a chip, comprising:
forming a chip stack structure, wherein the chip stack structure comprises a plurality of chips stacked onto one another, and any two adjacent chips of the plurality of chips are bonded together through the NCF according to claim 1; and
bonding the chip stack structure to a substrate, to realize packaging of the plurality of chips.

12. The method of claim 11, wherein forming the chip stack structure comprises:
providing a plurality of chips, wherein the NCF is arranged on a first face of each chip, and a metal interconnection layer is arranged on a second face of each chip, wherein the first face and the second face are two faces of each chip which are opposite to each other in a thickness direction of each chip;
aligning the first face of a first chip of the plurality of chips with the second face of a second chip of the plurality of chips; and
at least stacking the first chip on the second chip by the NCF to form the chip stack structure.

13. The method of claim 12, wherein the NCF at least comprises a first film layer and a second film layer,
a surface of the first film layer is provided with a grid-shaped groove structure, and a depth of each groove of the groove structure is less than a thickness of the first film layer,
the second film layer is located in the groove in the surface of the first film layer, and
fluidity of the first film layer is greater than fluidity of the second film layer under a same condition.

14. The method of claim 13, wherein a first surface of the first film layer is provided with a grid-shaped groove structure, and a supporting layer is arranged on a surface of the second film layer and a part of the first surface of the first film layer,
a second surface of the first film layer is in contact with the first face of the chip, and
the first surface and the second surface are two surfaces of the first film layer which are opposite to each other in a thickness direction of the first film layer.

15. The method of claim 14, further comprising:
removing the supporting layer before bonding the first chip to the second chip.

16. The method of claim 12, wherein at least stacking the first chip on the second chip by the NCF to form the chip stack structure comprises:
at least bonding the first chip to the second chip by the NCF through a vacuum bonding process and a Thermal Compression Bond (TCB) process, to obtain the chip stack structure.

17. The method of claim 16, wherein providing the plurality of chips comprises:
providing a wafer, wherein a circuit structure with a specific function is formed in the wafer;
forming the NCF on a surface of the wafer; and
cutting the wafer to form the plurality of chips.
